(19) United States
(12) Patent Application Publication
(10) Pub. No.: US 2002/0121242 A1
(43) Pub. Date: Sep. 5, 2002

(54) Heat-treatment apparatus, heat-treatment method using the same and method of producing a semiconductor device

(75) Inventors: Masashi Minami, Hyogo (JP); Ikuo Katsurada, Tokyo (JP)

Correspondence Address: McDERMOTT, WILL & EMERY, 600 13th Street, N.W., Washington, DC, 20005-3096, US

(73) Assignee: Mitsubishi Denki Kabushiki Kaisha and Ohmiya Corporation

(21) Appl. No.: 09/983,391

(22) Filed: Oct. 24, 2001

(30) Foreign Application Priority Data
Mar. 2, 2001 (JP) 2001-058186

(51) Int. Cl. C23C 16/00

(52) U.S. Cl. 118/724

(57) ABSTRACT

A plurality of jetting outlets having a jetting outlet shape of a Vincent Bach curve are disposed in a jetting part of a heat-treatment apparatus. An oxygen pipe, an air pipe, and an argon pipe are connected to the jetting part. A wafer supplied into a reaction tube is warmed and subjected to a heat treatment at a predetermined temperature. Thereafter, in cooling the wafer, a cooling gas containing oxygen is introduced from the jetting part into the reaction tube after the wafer is cooled to a predetermined temperature, whereby the wafer is further cooled. This restrains exfoliation of the film formed on the wafer.

### BACKGROUND OF THE INVENTION

1. Field of the Invention

The present invention relates to a heat-treatment apparatus, a heat-treatment method using the same, and a method of producing a semiconductor device. More particularly, the present invention relates to a heat-treatment apparatus providing an efficient cooling after a heat-treatment, a heat-treatment method using the same, and a method of producing a semiconductor device including a heat-treatment step.

2. Description of the Background Art

Semiconductor devices such as a MOSLSI (Metal Oxide Semiconductor Large Scale Integrated Circuit) and a bipolar LSI are produced through numerous steps involving heat treatments such as an oxidation step, a CVD (Chemical Vapor Deposition) step, and a diffusion step. Among these steps, there is a step of performing a heat treatment under a comparatively high temperature condition with a temperature higher than about 700° C. using a diffusion furnace, a reduced-pressure CVD furnace, or a RTA (Rapid Thermal Annealing).

RTA involves warming and cooling at a speed of around 100° C. per one second. A longitudinal type heat-treatment furnace involves warming at a speed of about 10° C. per one minute, and cooling at a speed of about 3° C. per one minute. For this reason, in order to ensure a high throughput, the period of time for warming and cooling excluding a substantial process of a wafer must be shortened, so that the wafer is put in and out usually at a temperature higher than about 650° C.

In a recently developed longitudinal-type heat-treatment furnace, a wafer is warmed at a temperature speed of about 50° C. or more per one minute, and cooled at a temperature speed of about 30° C. or more per one minute. This heat-treatment furnace is referred to as a high-speed warming/cooling furnace. By this high-speed warming/cooling furnace, the wafer can be introduced into a processing chamber at a temperature of 500° C. or less, and can be warmed to a predetermined temperature at a high speed.

Here, when a heat-treatment furnace capable of warming and cooling at a temperature condition of 30° C. or more was initially developed, the heat-treatment furnace was referred to as a high-speed warming/cooling furnace, and was distinguished from conventional heat-treatment furnaces; however, the warming/cooling rate is becoming higher in conventional-type heat-treatment furnaces as well, so that no clear distinction is made between the conventional-type heat-treatment furnaces and the high-speed warming/cooling furnaces.

In the case of performing an oxidation process in a longitudinal-type heat-treatment apparatus and taking out a wafer from the heat-treatment apparatus (for unloading) after cooling the wafer down to a temperature lower than 500° C. in a furnace, there arises a problem of extreme decrease in the life time of the wafer. The life time refers to a period of time till the peak of the minor carriers grown in the wafer (silicon substrate) by radiation of laser light having a predetermined wavelength onto the wafer decays to 1/e.

Decrease in life time means increase in the interface level if a metal pollutant such as iron is absent, and for example in a memory device, it means degradation of electrical properties, such as a change of threshold voltage of a transistor.

In order to avoid such decrease in the life time, there are proposed a method of bonding hydrogen (atom) to the dangling bond of silicon (atom) by introducing hydrogen during the cooling, and a method of reducing the surface voltage of the wafer by introducing water vapor to carry out reoxidation.

However, the oxidation step in the heat treatment is a step carried out at a comparatively early stage in the series of wafer production process. The life time repeatedly increases and decreases in the steps subsequent to the oxidation step. For this reason, the proposed methods are not decisive as a countermeasure for restraining the decrease in life time in the heat-treatment step carried out at an early stage of the series of wafer production process. Rather, there arises a problem in that application of an apparatus for introduction of hydrogen or introduction of water vapor causes overspecification.

Here, the overspecification herein mentioned refers to the need for introducing additional equipment such as described below. Namely, in handling hydrogen, there is a need to provide a leakage sensing system or explosion-preventing equipment in order to ensure safety. Further, introduction of water vapor during the cooling causes generation of water by condensation, so that there is a need to take a water drainage measure. Furthermore, in the case of introducing ozone, there is a need to introduce equipment for generating ozone.

Now, with the use of wafers for test, electrical properties were evaluated under an oxidation condition that was accompanied by decrease in life time and under an oxidation condition that was not accompanied by decrease in life time. It has been found out that there is little difference in the electrical properties between the two, thereby causing no problem. Here, in this case, the processing conditions other than the oxidation condition were maintained to be the same (common).

In semiconductor devices, it is necessary to avoid decrease in the life time in the end. For that purpose, the amount of surface electric charge must be lowered when the wafer processing steps are completed. From the experimental facts such as described above, it is necessary to find out which step is the most critical step in the series of wafer production process.

Furthermore, even if the difference in the electrical properties caused by the difference of the oxidation step is not recognized, it seems that a difference may be recognized, for example, in the number of dangling bonds of silicon. In particular, if the number of dangling bonds is large, it means that there is a large number of states in which silicon and oxygen are separated from each other, so that in this case there is a fear of film exfoliation of a film formed on the silicon substrate.

### SUMMARY OF THE INVENTION

The present invention has been made in order to solve the aforementioned problems of the prior art, and one object thereof is to provide a heat-treatment apparatus capable of improving the life time and restraining the film exfoliation without causing overspecification in the heat-treatment step. Another object thereof is to provide a heat-treatment method using the heat-treatment apparatus. Still another object thereof is to provide a method of producing a semiconductor device capable of improving the life time and restraining the film exfoliation.

A heat-treatment apparatus according to one aspect of the present invention is a heat-treatment apparatus for performing a heat treatment on a semiconductor substrate that is introduced into a processing chamber, wherein the heat-treatment apparatus includes a jetting outlet for jetting a cooling gas in a turbulent flow state onto the semiconductor substrate.

It has been experimentally confirmed that this structure allows efficient cooling of the semiconductor substrate by supplying a cooling gas in a turbulent flow state, whereby the life time is improved as compared with the case of conventional heat-treatment apparatus.

As a result of studies, it has been found out that, in order to jet the cooling gas in a turbulent flow state onto the semiconductor substrate, the jetting outlet preferably includes a jetting outlet shape that corresponds to a bell portion of a trumpet. Further, the jetting outlet preferably includes a jetting outlet shape that extends along a curve mathematically approximating a bell portion of a trumpet.

Further, it is preferable that the cooling gas contains a combination of nitrogen and an inert gas as a first cooling gas, and contains a combination of oxygen and nitrogen or a combination of oxygen and an inert gas as a second cooling gas, and the second cooling gas is jetted after the first cooling gas is jetted from the jetting outlet.

In this case, if the heat-treatment is carried out, for example, in a state in which a high-melting-point metal film or the like is formed on the semiconductor substrate as described later, the bonded state of silicon and oxygen increases in number, so that the life time is improved and the exfoliation of the high-melting-point metal film or the like from the semiconductor substrate can be restrained without oxidation of the high-melting-point metal film.

Further, the jetting outlet is preferably disposed separately from a jetting outlet that jets a gas for performing the heat treatment on the semiconductor substrate.

In this case, foreign substances such as a reaction product adhering to the jetting outlet that jets the gas for performing the heat-treatment are prevented from adhering onto the semiconductor substrate, and the semiconductor substrate can be cooled rapidly with a comparatively large amount of cooling gas.

A heat-treatment method according to another aspect of the present invention is a heat-treatment method using a heat-treatment apparatus that includes a jetting outlet for introducing a cooling gas in a turbulent flow state into a processing chamber, wherein the heat-treatment method includes: cooling an object-of-processing to a predetermined temperature while exposing the object-of-processing to an atmosphere of an inert gas after a heat-treatment is carried out on the object-of-processing; and further cooling the object-of-processing while exposing the object-of-processing to an atmosphere containing at least oxygen by introducing oxygen into the processing chamber after the object-of-processing is cooled to the predetermined temperature.

According to this method, if the heat-treatment is carried out, for example, in a state in which an electroconductive layer such as a polysilicon film or a high-melting-point metal film is formed on the semiconductor substrate as described later, the bonded state of silicon and oxygen increases in number, so that the life time is improved and the exfoliation of the electroconductive layer from the semiconductor substrate can be restrained without oxidizing the electroconductive layer.

A method of producing a semiconductor device according to still another aspect of the present invention includes: a step of forming electroconductive films on a semiconductor substrate; and a heat-treatment step of performing a heat treatment on the electroconductive films in a reaction chamber after the electroconductive films are formed. The heat-treatment step for performing the heat-treatment on the electroconductive films includes the cooling steps of: cooling the semiconductor substrate to a predetermined temperature while exposing the semiconductor substrate to an atmosphere of an inert gas; and further cooling the semiconductor substrate while exposing the semiconductor substrate to an atmosphere containing at least oxygen by introducing oxygen into the reaction chamber after the semiconductor substrate is cooled to the predetermined temperature.

According to this method, the state in which silicon and oxygen are bonded to each other will be sufficiently larger in number than the state in which silicon and oxygen are separated from each other at the interface between the semiconductor substrate and the electroconductive layer by further cooling the semiconductor substrate with the atmosphere containing oxygen after the semiconductor substrate is cooled to the predetermined temperature. As a result of this, the life time will be improved, and the exfoliation of the electroconductive layer from the semiconductor substrate can be prevented.

Further, it is preferable that the electroconductive films include at least one of a polysilicon film and a high-melting-point metal film, and the predetermined temperature in the heat-treatment step is a temperature such that the electroconductive films are not oxidized by oxygen.

In this case, the polysilicon film and the high-melting-point metal film can be prevented from being oxidized.

Further, it is preferable that at least the oxygen is supplied in a turbulent flow state into the reaction chamber in the heat-treatment step.

In this case, it has been experimentally confirmed that the semiconductor substrate can be efficiently cooled to improve the life time with certainty.

Furthermore, as a result of studies, it has been found out that, in order to supply oxygen in a turbulent flow state into the reaction chamber, the oxygen is preferably supplied into the reaction chamber from a jetting outlet having a shape that corresponds to a bell portion of a trumpet or a jetting outlet shape that extends along a curve mathematically approximating a bell portion of a trumpet.

Further, it is preferable that the method further includes the step of measuring a life time of minor carriers in the silicon substrate by using a life time measuring device after the heat-treatment step.

In this case, it will be comparatively easy to determine whether the electroconductive film or the like is prone to exfoliation or not after the heat-treatment step, on the basis of the correlation between the life time and the film exfoliation.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing each heat-treatment apparatus and heat-treatment condition that forms a basis for obtaining a heat-treatment apparatus according to a first embodiment of the present invention;

FIG. 2 is a view showing a life time under condition 8 shown in FIG. 1 in the first embodiment;

FIG. 3 is a view illustrating the coordinates for measuring a bell portion of a trumpet in the first embodiment;

FIG. 4 is a view showing values obtained by measuring the bell portion of the trumpet in the first embodiment;

FIG. 5 is a view illustrating an approximating portion and a connecting portion of the bell portion of the trumpet in the first embodiment;

FIG. 6 is a view illustrating an approximation of the bell portion of the trumpet with a polynomial of second order in the first embodiment;

FIG. 7 is a view illustrating an approximation of the bell portion of the trumpet with a polynomial of sixth order in the first embodiment;

FIG. 8 is a view illustrating an approximation of the bell portion of the trumpet with an exponential function in the first embodiment;

FIG. 9 is a view illustrating an approximation of the bell portion of the trumpet with a circular arc in the first embodiment;

FIG. 10 is a view illustrating a distribution of life time in a wafer surface under condition 9 shown in FIG. 1 in the first embodiment;

FIG. 11 is a perspective view of an experimental jetting part (nozzle) having a jetting outlet shape of a Vincent Bach curve in the first embodiment;

FIG. 12 is a perspective view of an experimental reaction tube in the first embodiment;

FIG. 13 is a view illustrating a flow of mist when the mist is supplied with the experimental jetting part mounted on the experimental reaction tube in the first embodiment;

FIG. 14 is a view illustrating a manner in which the mist flows from a hole disposed in the experimental reaction tube in the first embodiment;

FIG. 15 is a perspective view illustrating a heat-treatment apparatus in the first embodiment;

FIG. 16 is a perspective view illustrating the inside of the reaction tube in the first embodiment;

FIG. 17 is a partially enlarged perspective view of the jetting part shown in FIG. 16 in the first embodiment;

FIG. 18 is a cross-sectional view cut along a cross-sectional line XVIII-XVIII shown in FIG. 17 in the first embodiment;

FIG. 19 is a view illustrating a distribution of life time in a wafer surface under condition 10 shown in FIG. 1 in a heat-treatment method using a heat-treatment apparatus according to a second embodiment of the present invention;

FIG. 20 is a view for describing a mechanism of life time improvement in the second embodiment;

FIG. 21 is a view illustrating how the life time varies depending on heat-treatment conditions in a third embodiment of the present invention;

FIG. 22 is a cross-sectional view illustrating one step in a method of producing a semiconductor device according to the third embodiment of the present invention;

FIG. 23 is a view illustrating one example of a series of steps for heat-treatment in the third embodiment;

FIG. 24 is a view illustrating another example of a step for heat-treatment in the third embodiment;

FIG. 25 is a view illustrating a dimensional relationship of a jetting outlet shape of the heat-treatment apparatus in the first embodiment;

FIG. 26 is a perspective view of a conventional diffusion furnace;

FIG. 27 is a partially enlarged perspective view of the diffusion furnace shown in FIG. 26; and

FIG. 28 is a perspective view of a conventional RTA apparatus.

### DESCRIPTION OF THE PREFERRED EMBODIMENTS

First Embodiment

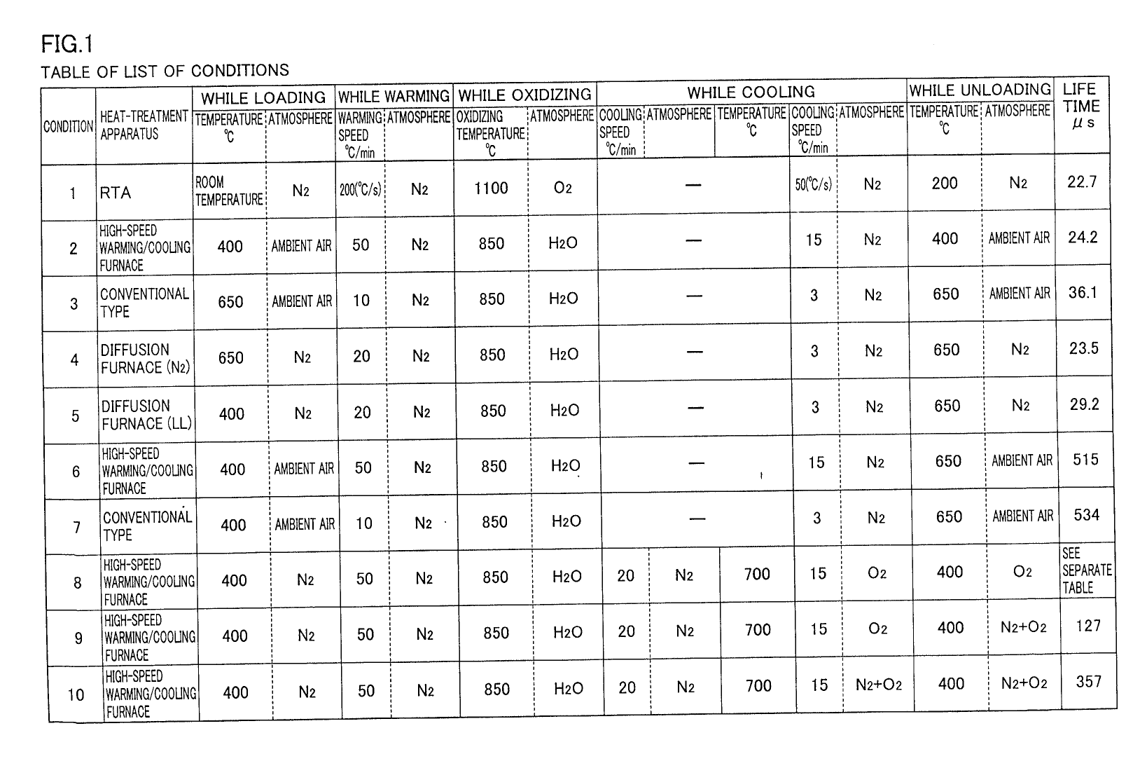

The inventors of the present invention have conducted various experiments as a preliminary stage for reaching the concept of the heat-treatment apparatus according to the invention. The results of these experiments will be hereafter described. First, with the use of various heat-treatment apparatus, the life time of minor carriers was measured. As the heat-treatment apparatus, RTA (lamp annealing apparatus), a high-speed warming/cooling furnace, a conventional-type diffusion furnace, a diffusion furnace equipped with an N₂ purging box, and a diffusion furnace equipped with a loading lock were put to use, as shown in the table of the list of conditions in FIG. 1.

Referring to FIG. 26, the high-speed warming/cooling furnace and the conventional-type diffusion furnace include a loading chamber 111 for putting a wafer 110 in and out, a wafer boat 109 for accommodating the wafer 110, and a reaction tube 117 for performing a heat treatment on the wafer 110. Wafer boat 109 is provided with a shutter 118 for closing the mouth of reaction tube 117. Further, a boat elevator 119 is provided for moving the wafer boat 109 upwards and downwards.

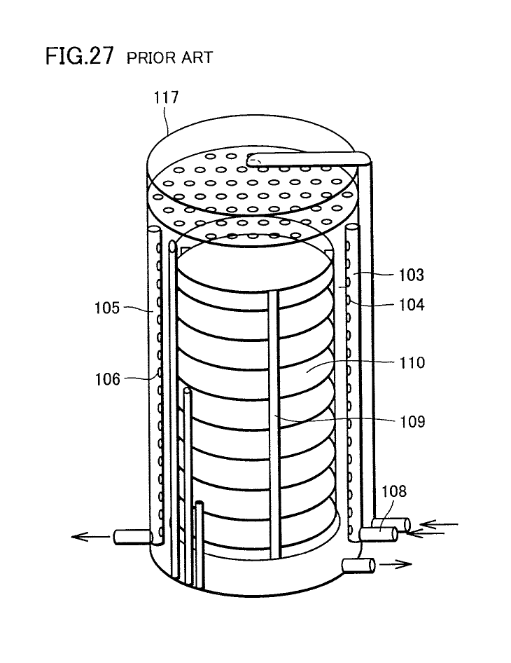

Referring to FIG. 27, a cooling gas ejecting part 103 is disposed in reaction tube 117 via a cooling gas introduction inlet 108. A cooling gas ejecting outlet 104 is disposed in cooling gas ejecting part 103. Further, a cooling gas discharging part 105 for discharging the cooling gas is disposed in reaction tube 117. A cooling gas discharging outlet 106 is disposed in cooling gas discharging part 105.

After the wafer is accommodated in wafer boat 109 located in loading chamber 111, wafer boat 109 is sent into reaction tube 117 by boat elevator 119. In reaction tube 117, the wafer is warmed, subjected to a heat treatment at a predetermined temperature, and cooled to a predetermined temperature. Thereafter, wafer boat 109 is returned to loading chamber 111, and the wafer is taken out.

The structures of the diffusion furnace equipped with an N₂ purging box and the diffusion furnace equipped with a loading lock are basically the same as the structure of the above-described high-speed warming/cooling furnace or the like. In particular, the diffusion furnace equipped with an N₂ purging box is loaded and unloaded with a wafer in an N₂ atmosphere by introducing N₂ into a loading area of the wafer, for example, into loading chamber 111.

The diffusion furnace equipped with a loading lock is loaded and unloaded with a wafer in an N₂ atmosphere, for example, by introducing N₂ after loading chamber 111 is vacuumized.

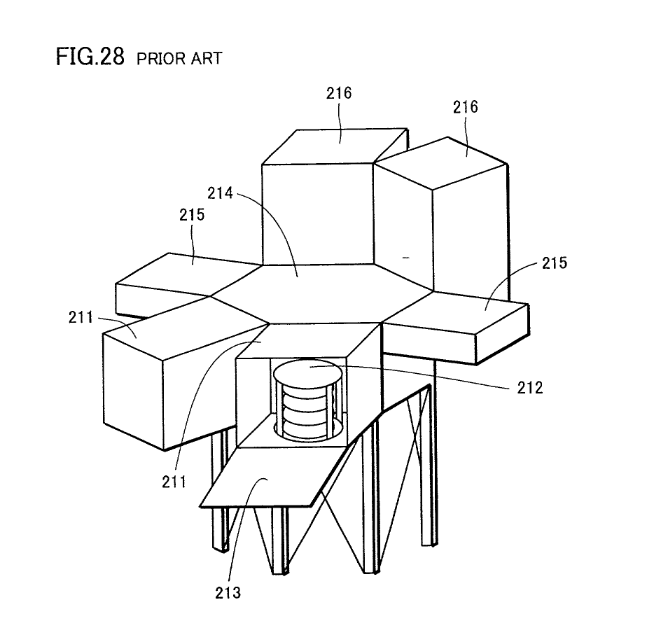

Referring to FIG. 28, the RTA includes a loading chamber 211 for accommodating a cassette 212 that stores a wafer, a reaction chamber 218 for performing a heat treatment on the wafer, a cooling chamber 215 for cooling the wafer subjected to the heat treatment, and a conveying chamber 214 for connecting loading chamber 211 and reaction chamber 216.

After cassette 212 is accommodated in loading chamber 211, a door 213 is closed and the inside of loading chamber 211 is substituted with N₂ at room temperature. The wafer in cassette 212 is sent to reaction chamber 216 via conveying chamber 214. In reaction chamber 216, the wafer is warmed, subjected to a heat treatment at a predetermined temperature, and cooled to a predetermined temperature. Thereafter, the wafer is sent to cooling chamber 215 to be further cooled, and returned to cassette 212 in loading chamber 211.

Next, the heat-treatment conditions will be described.

Condition 1 made use of a RTA as the heat-treatment apparatus. The wafer was introduced (for loading) at room temperature and in a nitrogen atmosphere. The wafer was warmed in an N₂ atmosphere, and oxidized at a temperature of 1100° C. and in an oxygen atmosphere. After the oxidation process, the atmosphere was substituted with an N₂ atmosphere, and the wafer was cooled. Then the wafer was taken out (for unloading) at a temperature of 200° C. and in N₂.

Condition 2 made use of a high-speed warming/cooling furnace as the heat-treatment apparatus. The wafer was introduced (for loading) at 400° C. and in ambient air. The wafer was warmed in an N₂ atmosphere, and oxidized at a temperature of 850° C. and in a water vapor atmosphere. After the oxidation process, the atmosphere was substituted with an N₂ atmosphere, and the wafer was cooled. Then the wafer was taken out (for unloading) at a temperature of 400° C. and in ambient air.

Condition 3 made use of a conventional-type diffusion furnace as the heat-treatment apparatus. The wafer was introduced (for loading) at 650° C. and in ambient air. The wafer was warmed in an N₂ atmosphere, and oxidized at a temperature of 850° C. and in a water vapor atmosphere. After the oxidation process, the atmosphere was substituted with an N₂ atmosphere, and the wafer was cooled. Then the wafer was taken out (for unloading) at a temperature of 650° C. and in ambient air.

Condition 4 made use of a diffusion furnace equipped with an N₂ purging box as the heat-treatment apparatus. The wafer was introduced (for loading) at 650° C. and in N₂. The wafer was warmed in an N₂ atmosphere, and oxidized at a temperature of 850° C. and in a water vapor atmosphere. After the oxidation process, the wafer was cooled. Then the wafer was taken out (for unloading) at a temperature of 650° C. and in an N₂ atmosphere.

Condition 5 made use of a diffusion furnace equipped with a loading lock as the heat-treatment apparatus. The wafer was introduced (for loading) at 400° C. and in an N₂ atmosphere. The wafer was warmed in an N₂ atmosphere, and oxidized at a temperature of 850° C. and in a water vapor atmosphere. After the oxidation process, the wafer was cooled. Then the wafer was taken out (for unloading) at a temperature of 650° C. and in an N₂ atmosphere.

Condition 6 made use of a high-speed warming/cooling furnace as the heat-treatment apparatus. The wafer was introduced (for loading) at 400° C. and in ambient air. The wafer was warmed in an N₂ atmosphere, and oxidized at a temperature of 850° C. and in a water vapor atmosphere. After the oxidation process, the atmosphere was substituted with an N₂ atmosphere, and the wafer was cooled. Then the wafer was taken out (for unloading) at a temperature of 650° C. and in ambient air.

Condition 7 made use of a conventional type diffusion furnace as the heat-treatment apparatus. The wafer was introduced (for loading) at 400° C. and in ambient air. The wafer was warmed in an N₂ atmosphere, and oxidized at a temperature of 850° C. and in a water vapor atmosphere. After the oxidation process, the atmosphere was substituted with an N₂ atmosphere, and the wafer was cooled. Then the wafer was taken out (for unloading) at a temperature of 650° C. and in ambient air.

Next, a heat treatment was carried out on a wafer (manufactured by Mitsubishi Material Co., Ltd., diameter: 300 mm (12 inch), P-type, crystal axis (100), specific resistance: 10 to 15 Ω·cm, oxygen concentration 1.1±0.1×10¹⁸/cm³) under the above-described conditions 1 to 7, and the life time was measured. As the life time measuring device, a life time scanner WTXA manufactured by SEMILAB Co., Ltd. was used. As the high-speed warming/cooling furnace, a high-speed warming/cooling type VF-5700 manufactured by Koyo Thermosystem Co., Ltd. was used. As the RTA, a trial-manufacture machine corresponding to 12-inch wafers was used.

By the heat treatment under conditions 1 to 5, the life time was within the range from about 20 to 40 μs, and the values were found to be considerably low. On the other hand, by the heat treatment under conditions 6 and 7, the life time was more than or equal to 500 μs, and the values were found out to be at a level that does not raise any problem. Under these two conditions, the wafer was taken out (for unloading) at a temperature of 650° C. and in ambient air, so that the wafer was exposed to an atmosphere containing 80% of nitrogen and 20% of oxygen.

From this, it will be understood that the life time can be improved by exposing the wafer to ambient air, nitrogen containing oxygen, or argon containing oxygen at the time of cooling and at the time of unloading, even if the wafer is not exposed to water vapor, ozone, or hydrogen.

Next, how the life time varies by introduction of oxygen during the cooling was examined. The heat treatment condition was set to be condition 8 shown in FIG. 1.

Condition 8 made use of a high-speed warming/cooling furnace as the heat-treatment apparatus. The wafer was introduced (for loading) at 400° C. and in an N₂ atmosphere. The wafer was warmed in an N₂ atmosphere, and oxidized at a temperature of 850° C. and in a water vapor atmosphere. After the oxidation process, the atmosphere was substituted with an N₂ atmosphere, and the wafer was cooled down to 700° C. Thereafter, the wafer was further cooled by introducing oxygen, and the wafer was taken out (for unloading) at a temperature of 400° C. and in an oxygen atmosphere. The temperature of 700° C. is a temperature such that the wafer is not oxidized by oxygen.

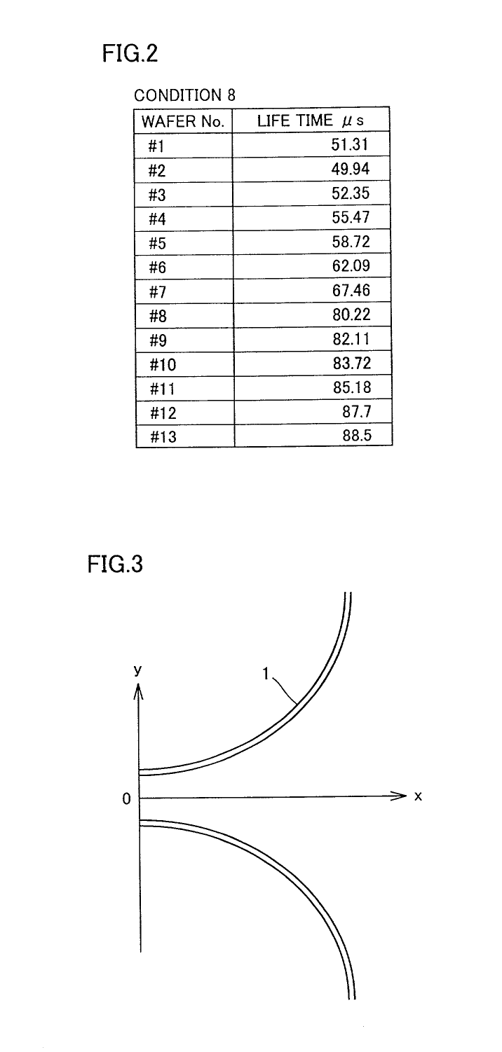

Thirteen sheets of wafers were used as samples. FIG. 2 shows the results of the measurement of the life time. Referring to FIG. 2, the life time was within the range from about 50 to 100 μs. As compared with conditions 1 to 5, the life time was improved; however, the values were found to be still unsatisfactory.

Next, as a factor for obtaining a satisfactory life time, the inventors considered that the cooling speed of the wafer may be related in addition to supplying oxygen during the cooling. Referring to FIG. 27, in a high-speed warming/cooling furnace, a cooling gas ejecting part 103 for introducing a cooling gas and a cooling gas discharging part 105 for discharging the cooling gas are disposed in reaction tube 117.

Therefore, the life time was examined by supplying a cooling gas into the reaction tube at the time of unloading. The heat treatment condition was set to be condition 9 shown in FIG. 1. Condition 9 made use of a high-speed warming/cooling furnace as the heat-treatment apparatus. The wafer was introduced (for loading) at 400° C. and in an N₂ atmosphere. The wafer was warmed in an N₂ atmosphere, and oxidized at a temperature of 850° C. and in a water vapor atmosphere. After the oxidation process, the atmosphere was substituted with an N₂ atmosphere, and the wafer was cooled down to 700° C. Thereafter, the wafer was further cooled down to a temperature of 400° C. by introducing oxygen. The wafer was taken out (for unloading) in an oxygen and nitrogen atmosphere by introducing nitrogen in addition to oxygen at the time of unloading.

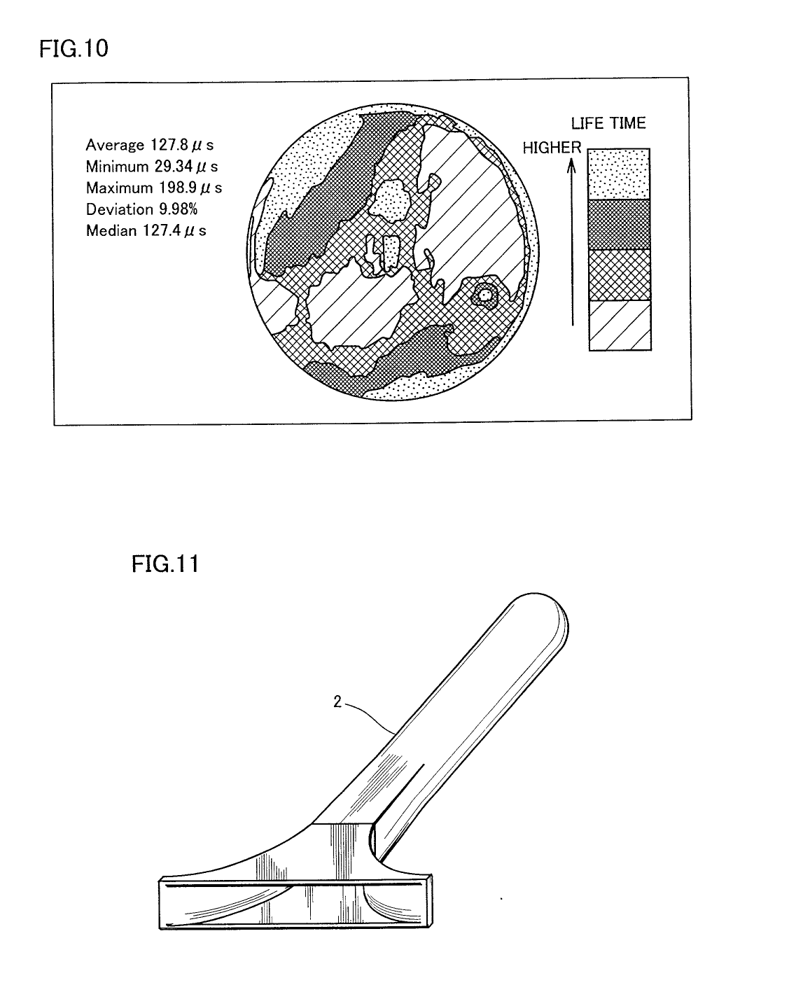

The result of measurement of the life time was about 127 μs, showing an improvement in the life time as compared with the case of condition 8. However, referring to FIG. 10, according to the distribution of the life time in the wafer surface, it has been found out that the distribution of life time is not circularly symmetric even though the wafer is rotating (revolving) in the reaction tube.

The inventors have considered that the reason why the distribution of life time is not circularly symmetric is that the jetting of the cooling gas has a directivity, and the cooling gas is not jetted uniformly onto the wafer. Thus, the inventors have reached a more efficient method of supplying the cooling gas uniformly onto the wafer.

In a heading “turbulent flow” in Scientific and Chemical Dictionary (published by Iwanami Shoten Co., Ltd.), it is stated that a large amount of substance can be transported by utilizing a turbulent flow. Therefore, in an attempt to search for a method capable of supplying a substance to every corner by utilizing a turbulent flow, the inventors have conceived an idea of a cooling gas jetting outlet utilizing a curve of a bell portion of a metal pipe musical instrument, particularly a trumpet that is considered as being capable of echoing a good sound to every corner of a concert hall. Specifically mentioned, a bell portion of a trumpet manufactured by Vincent Bach Co., Ltd., which is a widely used musical instrument among the trumpets and is considered to be an exquisite instrument, was selected as an object.

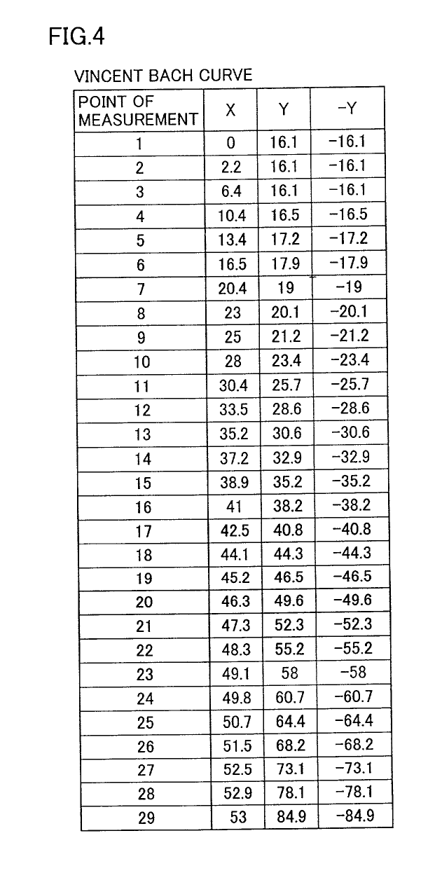

In order to fabricate a cooling gas jetting outlet utilizing the curve of this bell portion, the bell portion of an actual trumpet was measured. First, referring to FIG. 3, the center of rotational symmetry of the bell portion 1 was set to be the x-axis. The position distant by 53 mm from the jetting-side open end of the bell portion 1 was set to be the origin O. The direction passing through the origin O and being perpendicular to the x-axis was set to be the y-axis. The region from the origin O to the jetting-side open end of bell portion 1 was divided into 29 parts, and the value of the y-coordinate was measured for each x-coordinate. FIG. 4 shows the results.

The cooling gas jetting outlet utilizing the bell portion 1 may be fabricated on the basis of each numerical value shown in FIG. 4; however, for processing, it is preferable to approximate the curve with a numerical expression of some kind. Thus, an attempt was made to approximate the curve first with a polynomial or an exponential function. Referring to FIG. 5, the portion approximating the curve was set to be the portion whose x-coordinate value was 20.4 mm or more. Here, the portion directed to the origin from the approximating portion was set to be a connecting portion.

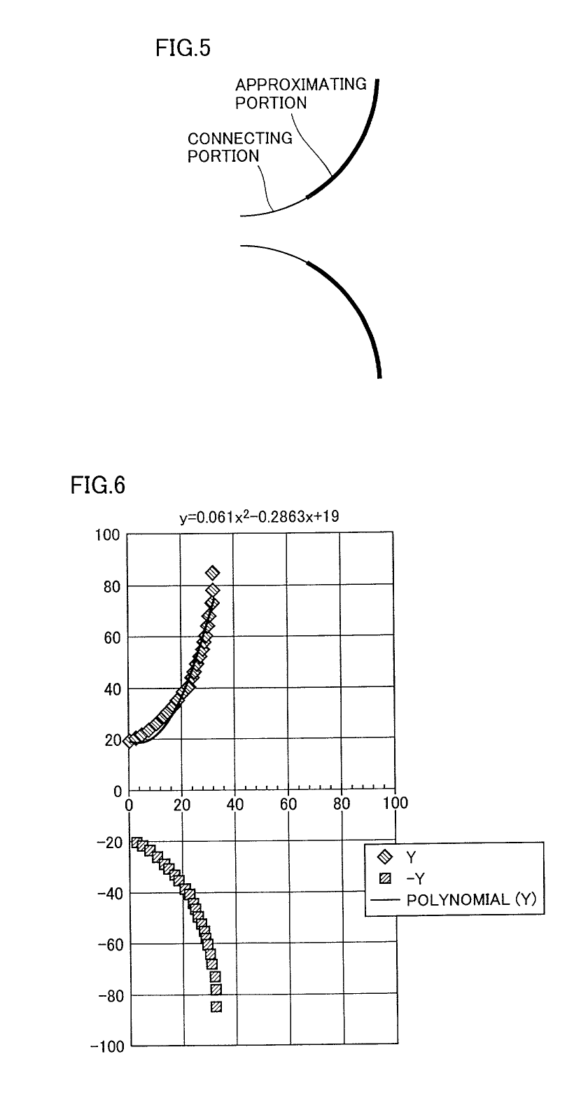

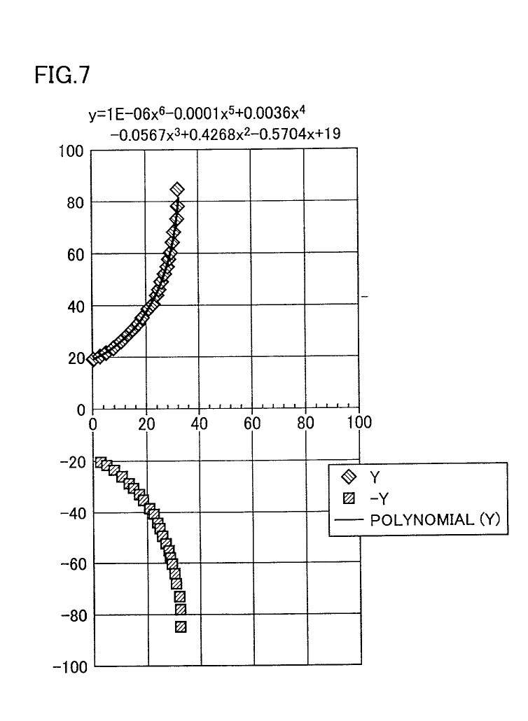

Referring to FIG. 6, a polynomial approximation of second order was found out to be smaller than the actually measured value at the jetting-side open end of the bell portion. Referring to FIG. 7, a polynomial approximation of sixth order was found out to be still smaller than the actually measured value at the jetting-side open end of the bell portion. It has been found out that, according as the order of approximation becomes higher, the polynomial approximation requires more labor than approximation of the curve based on proportional relationship using the measured values, so that the polynomial approximation lacks practicability.

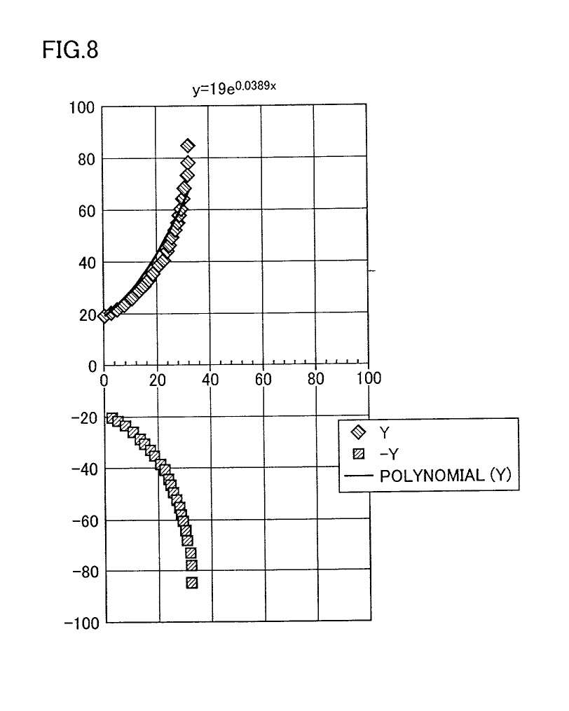

Further, referring to FIG. 8, exponential approximation was found out to be more out of the actually measured values than in the case of polynomial approximation of second order.

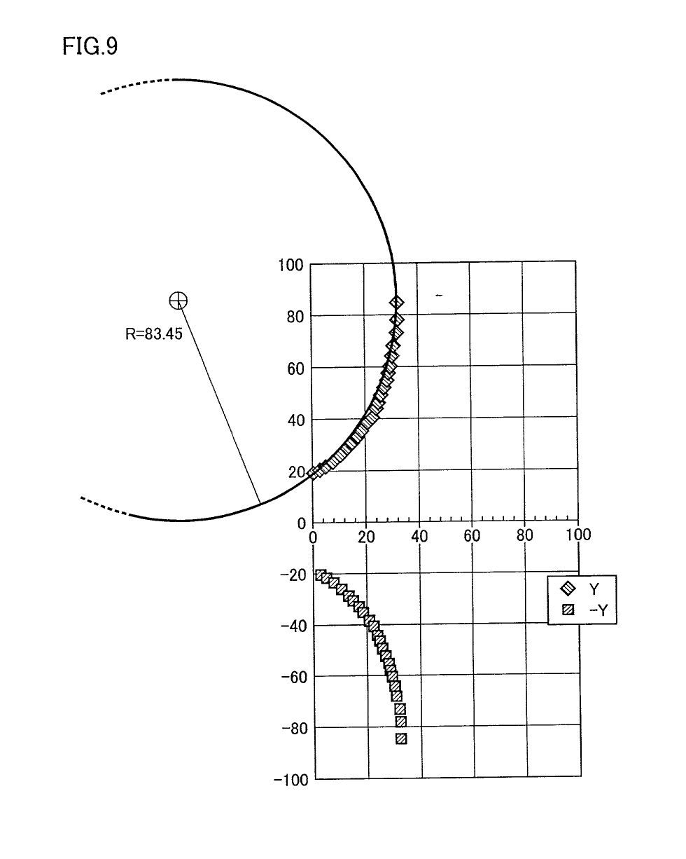

Next, the curve was approximated with a circular arc. Referring to FIG. 9, the circular arc approximation was found out to be well coincident with the actually measured values at the jetting-side open end and in the vicinity thereof, and in particular, when the radius of the circle was R=83.45 mm, a portion of the circle was found out to meet the actually measured values well.

Therefore, approximation with a circular arc was adopted for approximation of the curve. Here, an approximation with an elliptic curve was attempted; however, the result was almost a circular arc. In producing the jetting outlet, the approximating portion and the connecting portion were approximated with a quarter of a whole circle in view of facilitating the production.

The curve obtained on the basis of the measured values of the shape of the bell portion of the trumpet manufactured by Vincent Bach Co., Ltd. as well as the curve obtained by approximation of the curve of the bell portion with a circular arc are referred to as “Vincent Bach curve” by the inventors of the present invention.

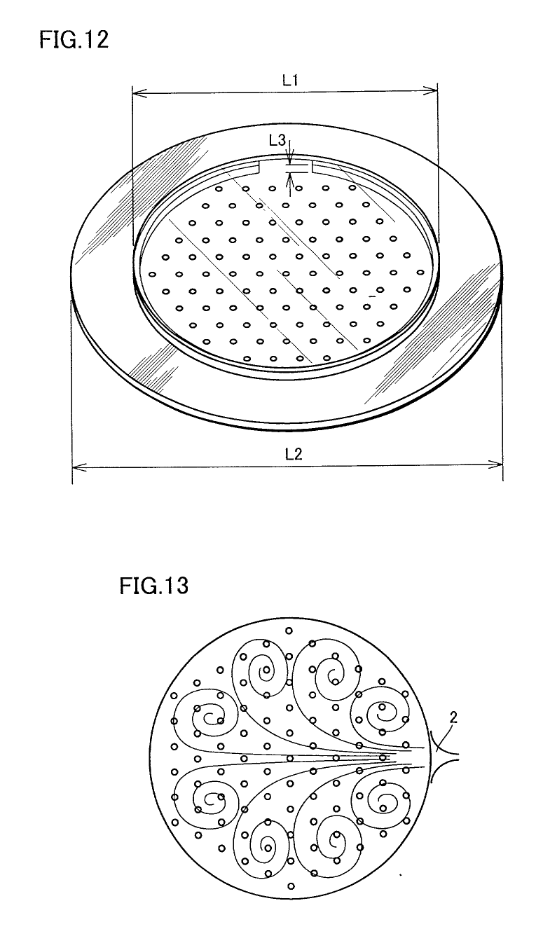

Next, a model was prepared to confirm the flow of cooling gas. First, FIG. 11 shows a jetting outlet (nozzle) 2 having a jetting outlet shape of a Vincent Bach curve. FIG. 12 shows an experimental reaction tube. The jetting outlet (nozzle) 2 and the experimental reaction tube were made of quartz. The dimensions of the experimental reaction tube were set to be such that L1=250 mm, L2=420 mm, and L3=15 mm.

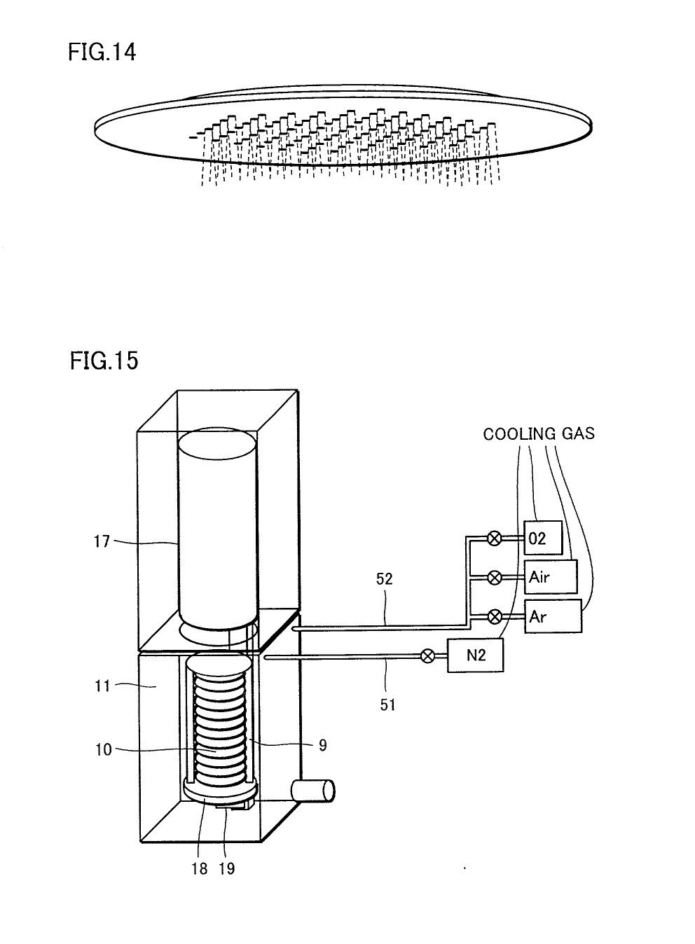

Jetting outlet (nozzle) 2 was mounted to the experimental reaction tube, and a mist was sent from the jetting outlet into the experimental reaction tube for examination of the flow of the mist. FIG. 13 shows a model view for illustrating the manner in which the mist flows. Referring to FIG. 13, it has been confirmed that the mist sent from the jetting outlet into the experimental reaction tube becomes a vortex and spreads rapidly towards the peripheries of the reaction tube. Referring to FIG. 14, at this time, it has been confirmed that the mist jets out uniformly from a plurality of holes disposed in the experimental reaction tube.

Particularly, in a RTA that cools the wafer at a speed of several ten ° C. per second, it is necessary to introduce a cooling gas rapidly, so that a jetting outlet having a jetting outlet shape of a Vincent Bach curve seems to be effective.

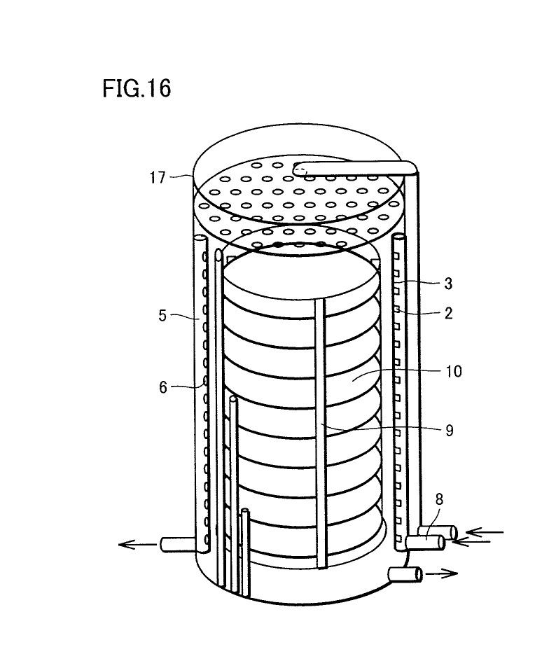

Next, a heat-treatment apparatus equipped with a cooling gas jetting part having a jetting outlet shape of the above-mentioned Vincent Bach curve will be described. Referring to FIGS. 15 and 16, the heat-treatment apparatus includes a loading chamber 11 for putting a wafer 10 in and out, a wafer boat 9 for accommodating wafer 10, and a reaction tube 17 for performing a heat treatment on wafer 10. Wafer boat 9 is provided with a shutter 18 for closing the mouth of reaction tube 17. Further, a boat elevator 19 for moving wafer boat 9 upwards and downwards is disposed.

Furthermore, the heat-treatment apparatus is provided with a cooling gas pipe 52 for jetting a cooling gas from a nozzle having a jetting outlet shape of a Vincent Bach curve in addition to a nitrogen pipe 51 which is conventionally disposed for cooling the wafer subjected to the heat treatment. An oxygen pipe, an air pipe, and an argon pipe are connected to cooling gas pipe 52.

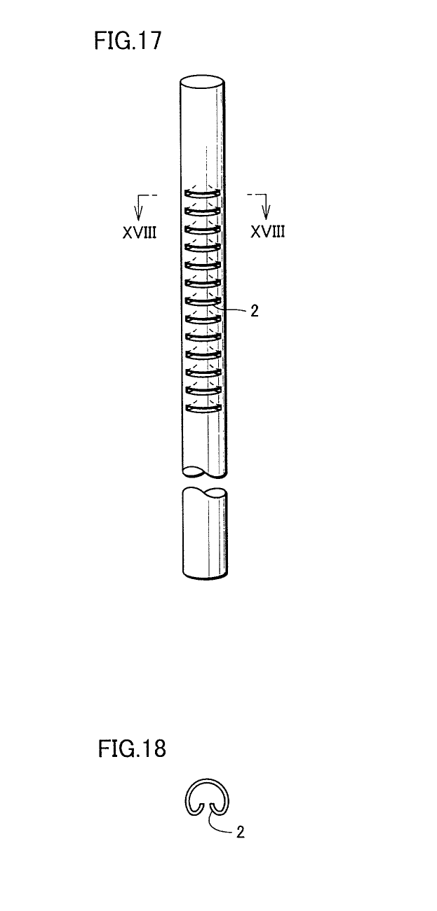

Referring to FIGS. 17 and 18, cooling gas jetting part 3 is provided with a plurality of jetting outlets 2 each having a jetting outlet shape of the above-mentioned Vincent Bach curve.

After the wafer is accommodated in wafer boat 9 located in loading chamber 11, wafer boat 9 is sent into reaction tube 17 by boat elevator 19. In reaction tube 17, the wafer is warmed, subjected to a heat treatment at a predetermined temperature, and then cooled to a predetermined temperature. Thereafter, wafer boat 9 is returned to loading chamber 11, where wafer 10 is taken out.

Second Embodiment

As the second embodiment of the present invention, a heat-treatment method using the heat-treatment apparatus described in the first embodiment will be described. First, the life time of minor carriers in a wafer (silicon substrate) was measured with the use of the above-described heat-treatment apparatus. The heat-treatment condition was set to be condition 10 shown in FIG. 1. Under condition 10, the wafer was introduced (for loading) at 400° C. and in an N₂ atmosphere. The wafer was warmed in an N₂ atmosphere, and oxidized at a temperature of 850° C. and in a water vapor atmosphere. After the oxidation process, the atmosphere was substituted with an N₂ atmosphere, and the wafer was cooled down to 700° C. Thereafter, the wafer was further cooled down to a temperature of 400° C. by introducing oxygen. The wafer was taken out (for unloading) in an oxygen and nitrogen atmosphere at the time of unloading.

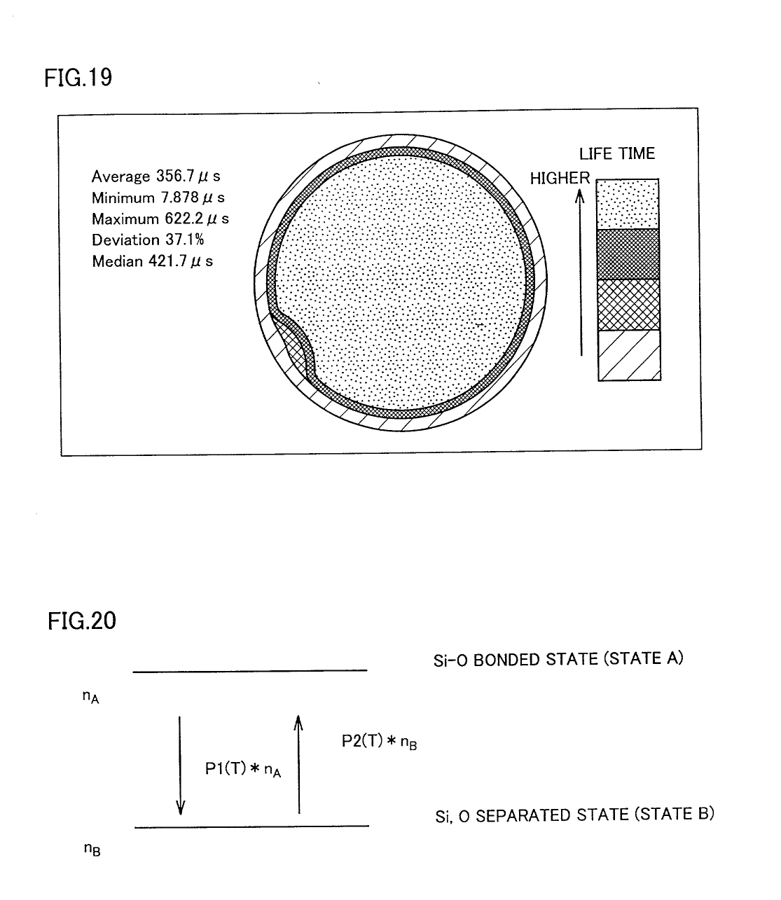

The value of the life time was about 356.7 μs, showing an improvement in the life time as compared with the case of condition 9. FIG. 19 shows a distribution of life time in the wafer surface. Referring to FIG. 19, it has been found out that the surface distribution of life time is near to a circularly symmetric one, and also the distribution width of the life time is narrowed. Thus, it has been found out that, by adopting a jetting outlet shape having a Vincent Bach curve as the cooling gas jetting part (jetting outlet), the wafer is cooled rapidly and uniformly.

Such an improvement in the life time seems to be due to the following reasons. In the oxidation process of a wafer having a diameter of 12 inch, a phenomenon of decrease in the recombination life time (μ-PCD) is recognized if the temperature of drawing out the wafer from the heat-treatment apparatus is a comparatively low temperature of 500° C. or lower.

For consideration, the recombination life time is divided into a bulk recombination life time and a surface combination life time. In this case, decrease due to bulk accompanying the experimental heat treatment was not recognized. Further, with regard to the decrease due to surface, no correlation with hydrogen was recognized.

From this, it seems that the decrease in the life time is caused by decrease in the surface recombination life time due to the change in the bonded state of silicon and oxygen at the interface between silicon (Si) and silicon oxide film (SiO₂). As the interface between silicon (Si) and silicon oxide film (SiO₂), there are an interface between the silicon substrate and the silicon oxide film and an interface between the silicon oxide film and the polysilicon film formed on the silicon oxide film.

The cause of decrease in the life time will be further conjectured in detail. The recombination life time (τ) is represented as 1/τ=1/τb+1/ τs using the bulk recombination life time (τb) and the surface recombination life time (τs). As one possibility for decrease in the bulk recombination life time (τb), the effect of thermal donors at the low-temperature cooling time was examined; however, the effect of the thermal donors was not recognized.

Further, the life time was measured by removing the oxide film and letting τs common in the wafer in which the decrease in τ is recognized and in the wafer in which the decrease in τ is not recognized; however, no difference was recognized between the two. From this, it seems that the decrease in τb does not occur even if τ decreases. Therefore, the decrease in the life time is caused not by the change in the life time in the bulk but by the change in the surface recombination life time at the interface between silicon (Si) and silicon oxide film (SiO₂).

As a factor that affects the recombination life time at the interface between silicon and silicon oxide film, hydrogen (H) or a bonded state of SiO at this interface may be related. From the fact that no correlation is recognized between the elimination temperature of hydrogen and the decrease temperature of life time by TDS (thermal desorption) measurement and from the fact that the life time recovers only in the heat treatment in a nitrogen atmosphere, it seems that the decrease in the life time is not due to the influence of hydrogen at the interface.

Thus, assuming that the decrease in the life time is due to the change in the bonded state of SiO at the interface, the dependency of life time on the heat-treatment temperature will be qualitatively explained. Referring to FIG. 20, at the interface between the silicon substrate (Si) and the silicon oxide film (SiO₂), the density of the state in which silicon (Si) and oxygen (O) are bonded to each other (SiO₂: state A) will be denoted as n_{A}; the density of the state in which silicon (Si) and oxygen (O) are separated from each other (Si, O: state B) will be denoted as n_{B}; the probability of transition from the state A to state B will be denoted as P1; the probability of transition from state B to state A will be denoted as P2; and the interface trap density generated in the separated state will be denoted as Itr. Then, Itr seems to be given by the following formula:

Itr=∫(P1(T)×n_{A}−P2(T)×n_{B})dT (formula 1)

(Lower limit of integration=T1, upper limit of integration=T2). Here, T1 represents a temperature of starting the heat treatment, and T2 represents a temperature of ending the heat treatment.

A good SiO bonded state is formed in the wafer after oxidation, and the state density n_{A} is higher than the state density n_{B}, so that the integrand in the formula 1 is positive. Since the separated state (state B) increases in number by the heat treatment, the life time decreases.

The temperature dependency of the life time in the heat treatment at a single temperature is attributed to the temperature dependency of the transition probability P1(T). In the case of a cooling heat treatment, the contribution at each temperature adds, so that the decrease in the life time is conspicuous as compared with the case of heat treatment at a single temperature.

The state in which the life time is considerably decreased by the cooling heat treatment is a state in which the SiO bond is separated, and in this case the dangling bonds of silicon seem to be present. It seems that, in this state, the state density n_{A} is lower than the state density n_{B}, and the integrand in the formula 1 is negative, so that Itr decreases by the heat treatment to recover (improve) the life time.

Here, oxygen was introduced when the temperature became 700° C. during the cooling; however, it is preferable to introduce oxygen in a temperature range from about 600 to 700° C. Also, the wafer was cooled down to 400° C. after the introduction of oxygen; however, the wafer is preferably cooled down to a temperature range from about 500° C. to room temperature.

Third Embodiment

In the third embodiment, a production method for restraining the film exfoliation by using the above-mentioned heat-treatment apparatus will be described. In the first and second embodiments, a heat-treatment apparatus capable of improving the life time in the heat-treatment step and a heat-treatment method using the heat-treatment apparatus were described. The life time changes for each heat treatment.

For example, when a wafer having a life time of 23.0 μs after the heat treatment by RTA was subjected to a heat treatment at a temperature of 400° C. in a 3% hydrogen atmosphere, the life time became 297.5 μs. Further, when a wafer having a life time of 23.34 μs after the heat treatment by RTA was subjected to a heat treatment at a temperature of 450° C. in a 3% hydrogen atmosphere, the life time became 565.0 μs.

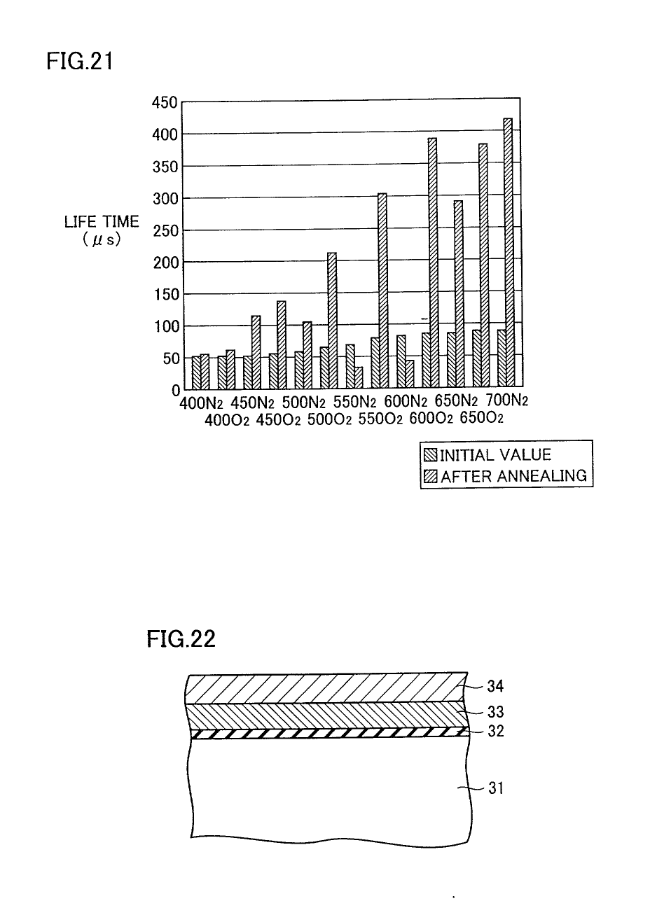

Further, it will be understood that, when thirteen sheets of wafers subjected to a heat treatment under condition 8 shown in FIG. 1 are subjected to a heat treatment under various conditions (temperature, atmosphere), the life time changes greatly as shown in FIG. 21.

Further, when a phosphorus-doped polysilicon film was formed on a wafer on which an oxide film having a film thickness of 60 nm had been formed by a heat treatment under condition 8, the life time which was about 50 μs immediately after the oxidation rose up to about 1000 μs. Further, when the wafer was introduced (for loading) at 700° C., subjected to a heat treatment at a temperature of 850° C. in a nitrogen atmosphere for 30 minutes, and taken out (for unloading) at 700° C. in order to crystallize the phosphorus-doped polysilicon film, the life time rose up to about 2400 μs.

This value of the life time corresponds to the value of the life time in a state in which the surface voltage is almost completely neutralized by corona discharge. Such variation in the life time seems to be due to increase and decrease in the surface combination level accompanying the disconnection and connection of the bond between oxygen and silicon in the oxide film by the heat treatment on the surface of the silicon substrate.

In semiconductor devices, if there is no problem in the life time in the end, there will be no problem in the electrical properties such as change in the threshold voltage of a transistor. However, if one considers whether there is any problem accompanying the change in life time, the following problem is feared.

If the life time is comparatively short, it is a state in which the dangling bond of silicon in the silicon substrate is comparatively large in number. If for example a high-melting-point metal film is formed on such a silicon substrate in a state in which the dangling bond is comparatively large in number, there is a possibility that the film exfoliation of a film including the high-melting-point metal film and the oxide film may occur due to the difference in the amount of warping between the silicon substrate and the oxide film in the heat treatment.

Indeed, it has been confirmed that the high-melting-point metal film is prone to exfoliation by performing a heat treatment under a condition with a temperature of 850° C. in a nitrogen atmosphere and cooling the silicon substrate down to a temperature of 600° C. Therefore, the life time was confirmed under the following condition.

As described before, when a phosphorus-doped polysilicon film was formed on a wafer on which an oxide film having a film thickness of 60 nm had been formed by a heat treatment based on condition 8 shown in FIG. 1, the life time which was about 50 μs immediately after the oxidation rose up to about 1000 μs. Thereafter, when the wafer was introduced (for loading) at 400° C., subjected to a heat treatment at a temperature of 850° C. in a nitrogen atmosphere for 30 minutes, and the wafer was taken out (for unloading) at 400° C., the life time decreased to about 200 μs.

The fact that the life time lowered shows an increased number of non-bonded states in which the bond between the silicon in the silicon substrate and the oxygen in the oxide film and the bond between the silicon in the polysilicon film and the oxygen in the oxide film are disconnected. In other words, this seems to make the film exfoliation liable to occur.

In an atmosphere containing oxygen, the transition probability P2 from state B to state A in the aforementioned formula 1 is larger than the transition probability P1 from state A to state B. Further, when the cooling speed is comparatively large, the effect of exfoliation due to the heat treatment decreases, and the effect of the bond between silicon and oxygen increases by an oxygen atmosphere. From these, the decrease in life time can be restrained, and the film exfoliation can be restrained.

Therefore, by further cooling the wafer in a uniform atmosphere containing oxygen and an inert gas in a state in which the temperature has become lower than or equal to 700° C. with the use of the present heat-treatment apparatus, silicon and oxygen are sufficiently bonded to improve the life time. Further, since the increase of the non-bonded states of silicon and oxygen is restrained, the exfoliation of the high-melting-point metal film can be prevented. In particular, if the heat treatment is carried out in a state in which another film such as a high-melting-point metal film has been formed on an oxide film, the film exfoliation can be prevented by application of the present heat-treatment apparatus.

The process of further cooling the wafer in an atmosphere containing oxygen and an inert gas in a state in which the temperature has become lower than or equal to 700° C. at the time of cooling in the aforesaid heat-treatment, is not limited to the present heat-treatment apparatus but can be applied in a heat treatment using another conventional heat-treatment apparatus as well.

First, referring to FIG. 22, a high-melting-point metal silicide film 34 such as tungsten silicide is formed through the intermediary of a silicon oxide film 32 and a polysilicon film 33 formed on a silicon substrate 31. Thereafter, a predetermined heat treatment is carried out using a RTA or a high-speed warming/cooling furnace.

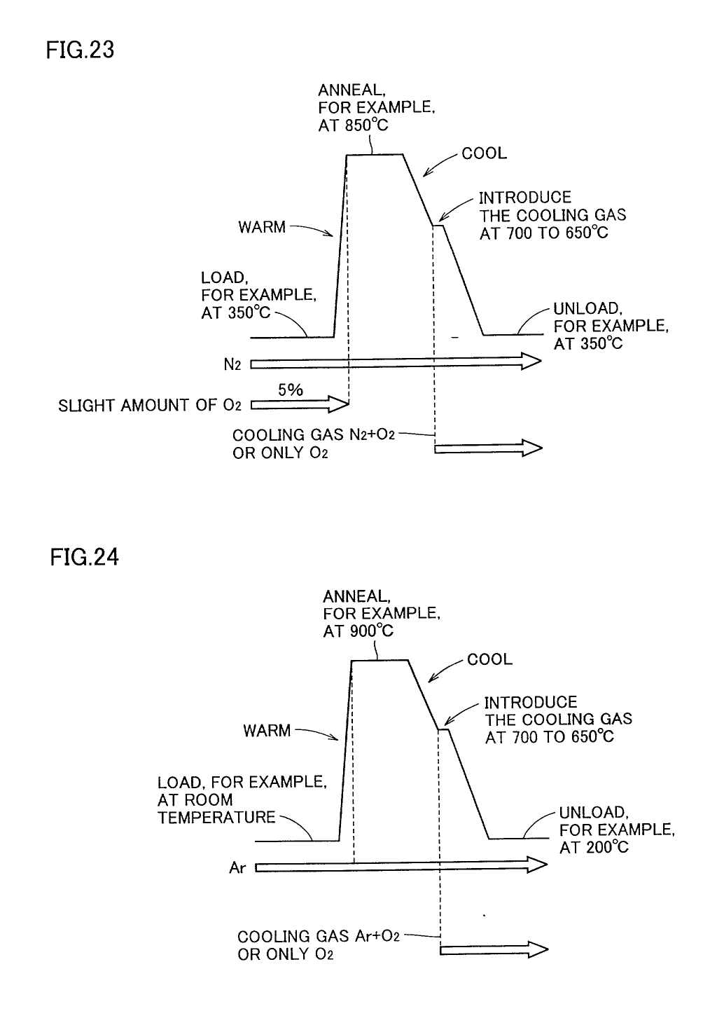

For example, referring to FIG. 23, as a heat treatment, a wafer is introduced (for loading) at 350° C. and subjected to a heat treatment at a temperature of 850° C. in a nitrogen atmosphere, and the wafer is taken out (for unloading) at 350° C. At the time of cooling after the heat treatment, the wafer is cooled down to a temperature lower than or equal to about 700° C. in a nitrogen atmosphere, and at that time point, oxygen is added to cool the wafer.

Further, referring to FIG. 24, as a heat treatment, a wafer is introduced (for loading) at 350° C. and subjected to a heat treatment at a temperature of 900° C. in an argon atmosphere, and the wafer is taken out (for unloading) at 350° C. At the time of cooling after the heat treatment, the wafer is cooled down to a temperature lower than or equal to about 700° C. in an argon atmosphere, and at that time point, oxygen is added to cool the wafer.

Here, if a RTA is to be applied, it is preferable that the warming speed is about 100 to 300° C./second, the heat treatment time is from about 15 to 90 seconds, and the cooling speed is about 50° C./second. Further, if a high-speed warming/cooling furnace is to be applied, it is preferable that the warming speed is about 30 to 100° C./second, the heat treatment time is from about 20 to 30 minutes, and the cooling speed is from about 30 to 15° C./minute.

Further, the wafer may be cooled with oxygen alone instead of being cooled with a mixture gas of oxygen and nitrogen or with a mixture gas of oxygen and argon gas.

As described above, in this heat treatment, oxygen is introduced in a state in which the temperature has lowered to 700° C. or less. When SiO₂ is formed by subjecting a high-melting-point metal silicide film to a heat treatment in an atmosphere containing oxygen, the silicon in the silicide film will be consumed. If the silicon in the silicide film is consumed and disappears, the silicon in the polysilicon film will be further consumed.

For this reason, unevenness (projections and recesses) is formed on the surface of the high-melting-point metal silicide film 34 shown in FIG. 22 after the heat-treatment, thereby apparently exhibiting a black appearance. When the oxidation further proceeds, the high-melting-point metal silicide film 34 becomes a WO gas to disappear. In order to prevent such a phenomenon, it is important that the heat treatment is carried out in an atmosphere that does not contain oxygen.

However, when a heat treatment is performed in an atmosphere that does not contain oxygen, the bonded state of silicon and oxygen decreases in number, and the film exfoliation becomes liable to occur, as described above. In other words, the high-melting-point metal silicide film 34 and the polysilicon film 33 shown in FIG. 22 may possibly exfoliate from the interface between the polysilicon film 33 and the silicon oxide film 32 or from the interface between the silicon oxide film 32 and the silicon substrate 31.

Therefore, in performing a heat treatment on a high-melting-point metal silicide film or the like, the disappearance of silicon, high-melting-point metal silicide film, or the like can be restrained by addition of oxygen in a state in which the silicon substrate has been cooled down to a temperature such that the high-melting-point metal silicide film or the like is not oxidized. By cooling the silicon substrate in an oxygen atmosphere, the bonded state of silicon and oxygen increases in number, thereby preventing the film exfoliation and improving the life time.

Further, from the above, by obtaining the correlation data between the life time and the film exfoliation, it is possible to easily evaluate the film exfoliation of the high-melting-point metal silicide film or the like after the heat treatment.

In other words, after the heat treatment is carried out, the life time of the minor carriers in the silicon substrate is measured with the life time measuring device, and the measured values are compared with the correlation data between the life time and the film exfoliation obtained in advance, whereby the measured values of the life time can be used as a criterion for determining whether the high-melting-point metal film is prone to exfoliation or not after the heat treatment.

For example, it seems that the film exfoliation is unlikely to occur if the value of the life time is more than or equal to 1000 μs after the heat treatment is performed using a wafer having an impurity such as iron (Fe) at a concentration of 10×10¹⁰/cm³ or less and forming a polysilicon film on an oxide film.

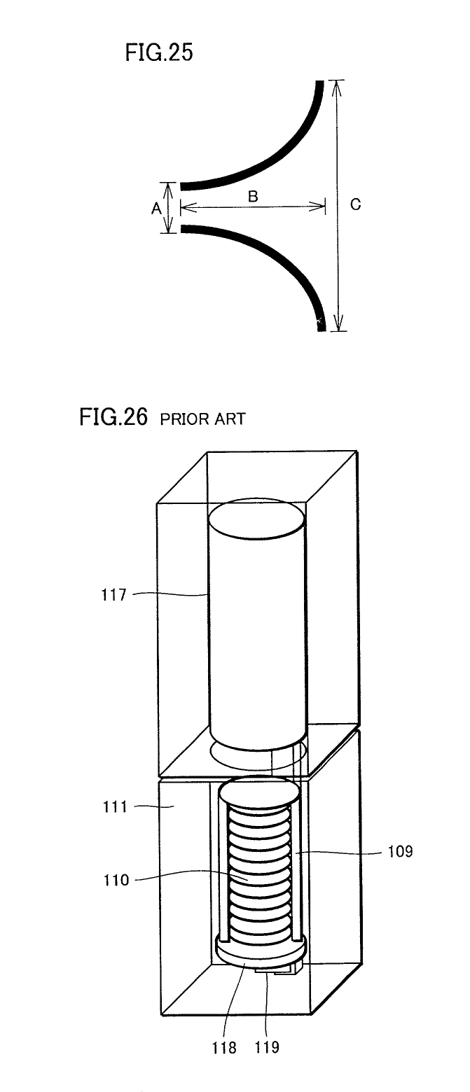

Here, the jetting part having a cooling gas jetting outlet shape of a Vincent Bach curve disposed in the present heat-treatment apparatus is preferably formed to have the dimensions A, B, and C shown in FIG. 25 in a ratio of A:B:C=about 3:4.8 to 6.5:15.8 to 16.2.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A heat-treatment apparatus for performing a heat treatment on a semiconductor substrate that is introduced into a processing chamber, wherein said heat-treatment apparatus comprises a jetting outlet for jetting a cooling gas in a turbulent flow state onto said semiconductor substrate.

2. The heat-treatment apparatus according to claim 1, wherein said jetting outlet includes a jetting outlet shape that corresponds to a bell portion of a trumpet.

3. The heat-treatment apparatus according to claim 2, wherein said cooling gas contains a combination of nitrogen and an inert gas as a first cooling gas, and contains a combination of oxygen and nitrogen or a combination of oxygen and an inert gas as a second cooling gas, and wherein said second cooling gas is jetted after said first cooling gas is jetted from said jetting outlet.

4. The heat-treatment apparatus according to claim 2, wherein said jetting outlet is disposed separately from a jetting outlet that jets a gas for performing the heat treatment on said semiconductor substrate.

5. The heat-treatment apparatus according to claim 1, wherein said jetting outlet includes a jetting outlet shape that extends along a curve mathematically approximating a bell portion of a trumpet.

6. The heat-treatment apparatus according to claim 3, wherein said cooling gas contains a combination of nitrogen and an inert gas as a first cooling gas, and contains a combination of oxygen and nitrogen or a combination of oxygen and an inert gas as a second cooling gas, and wherein said second cooling gas is jetted after said first cooling gas is jetted from said jetting outlet.

7. The heat-treatment apparatus according to claim 3, wherein said jetting outlet is disposed separately from a jetting outlet that jets a gas for performing the heat treatment on said semiconductor substrate.

8. The heat-treatment apparatus according to claim 1, wherein said cooling gas contains a combination of nitrogen and an inert gas as a first cooling gas, and contains a combination of oxygen and nitrogen or a combination of oxygen and an inert gas as a second cooling gas, and wherein said second cooling gas is jetted after said first cooling gas is jetted from said jetting outlet.

9. The heat-treatment apparatus according to claim 1, wherein said jetting outlet is disposed separately from a jetting outlet that jets a gas for performing the heat treatment on said semiconductor substrate.

10. A heat-treatment method using a heat-treatment apparatus that includes a jetting outlet for introducing a cooling gas in a turbulent flow state into a processing chamber, said heat-treatment method including:
cooling an object-of-processing to a predetermined temperature while exposing the object-of-processing to an atmosphere of an inert gas after a heat-treatment is carried out on the object-of-processing; and
further cooling the object-of-processing while exposing the object-of-processing to an atmosphere containing at least oxygen by introducing oxygen into said processing chamber after the object-of-processing is cooled to said predetermined temperature.

11. A method of producing a semiconductor device, comprising:
a step of forming electroconductive films on a semiconductor substrate; and
a heat-treatment step of performing a heat treatment on said electroconductive films in a reaction chamber after said electroconductive films are formed,
wherein said heat-treatment step includes the cooling steps of:
cooling the semiconductor substrate to a predetermined temperature while exposing the semiconductor substrate to an atmosphere of an inert gas; and
further cooling the semiconductor substrate while exposing the semiconductor substrate to an atmosphere containing at least oxygen by introducing oxygen into said reaction chamber after the semiconductor substrate is cooled to said predetermined temperature.

12. The method of producing a semiconductor device according to claim 11, wherein
said electroconductive films include at least one of a polysilicon film and a high-melting-point metal film, and
said predetermined temperature in said heat-treatment step is a temperature such that said electroconductive films are not oxidized by oxygen.

13. The method of producing a semiconductor device according to claim 11, wherein at least said oxygen is supplied in a turbulent flow state into said reaction chamber in said heat-treatment step.

14. The method of producing a semiconductor device according to claim 13, wherein said oxygen is supplied into said reaction chamber from a jetting outlet having a shape that corresponds to a bell portion of a trumpet or a jetting outlet shape that extends along a curve mathematically approximating a bell portion of a trumpet in said heat-treatment step.

15. The method of producing a semiconductor device according to claim 11, further comprising the step of measuring a life time of minor carriers in said silicon substrate by using a life time measuring device after said heat-treatment step.
